(19) United States
(12) Patent Application Publication
(10) Pub. No.: US 2024/0047443 A1
(43) Pub. Date: Feb. 8, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Jia LIU, Yokohama Kanagawa (JP); Tatsuo TONEDACHI, Yamato Kanagawa (JP)

(21) Appl. No.: 18/174,431

(22) Filed: Feb. 24, 2023

(30) Foreign Application Priority Data
Aug. 8, 2022 (JP) 2022-126330

(51) Int. Cl. H01L 25/16; H01L 23/00

(52) U.S. Cl. CPC H01L 25/167; H01L 24/08; H01L 24/32; H01L 24/48; H01L 24/49; H01L 2224/08113; H01L 2224/08123; H01L 2224/08237; H01L 2224/32058; H01L 2224/32137; H01L 2224/32145; H01L 2224/4903; H01L 2224/48137; H01L 2224/48464; H01L 2924/12041; H01L 2924/12043; H01L 2924/13091

(57) ABSTRACT

According to one embodiment, a semiconductor device includes a substrate, a first element and a second element on or above a first surface of the substrate, the first element and the second element each including a first terminal, a second terminal, and a gate, a light emitter, a light receiver configured to place the first element and the second element in an ON state or an OFF state according to an emitting state of the light emitter, and a first interconnect electrically coupling the first terminal of the first element and the first terminal of the second element to each other, the first interconnect being a sheet-shaped conductor.

### CROSS-REFERENCE TO RELATED APPLICATION(S)

This application is based upon and claims the benefit of priority from Japanese Patent Application No. 2022-126330, filed Aug. 8, 2022, the entire contents of which are incorporated herein by reference.

### FIELD

Embodiments described herein relate generally to a semiconductor device.

### BACKGROUND

A photorelay device is known as a type of a semiconductor device. A photorelay device includes a light emitter and a light receiver. A photorelay device is a contactless relay used for transmission of alternating current (AC) signals and direct current (DC) signals.

### BRIEF DESCRIPTION OF THE DRAWINGS

FIG. 1 is a circuit diagram for illustrating an exemplary circuit configuration of a semiconductor device according to an embodiment.

FIG. 2 is a plan view showing an exemplary planar structure of the semiconductor device according to the embodiment.

FIG. 3 is a sectional view taken along the line III-III indicated in FIG. 2, and shows an exemplary sectional structure of the semiconductor device according to the embodiment.

FIG. 4 is a graph showing changes in transmission characteristics with respect to frequencies in each of the case of using the semiconductor device according to the embodiment and the case of using a semiconductor device according to a comparative example.

FIG. 5 is a sectional view showing an exemplary sectional structure of a semiconductor device according to a first modification.

FIG. 6 is a sectional view showing an exemplary sectional structure of a semiconductor device according to a second modification.

### DETAILED DESCRIPTION

In general, according to one embodiment, a semiconductor device includes a substrate, a first element and a second element on or above a first surface of the substrate, the first element and the second element each including a first terminal, a second terminal, and a gate, a light emitter, a light receiver configured to place the first element and the second element in an ON state or an OFF state according to an emitting state of the light emitter, and a first interconnect electrically coupling the first terminal of the first element and the first terminal of the second element to each other, the first interconnect being a sheet-shaped conductor.

Embodiments will be described with reference to the drawings. The description will use the same reference symbols for the structural features or components having the same or substantially the same functions and configurations.

### 1. Embodiments

A semiconductor device according to some embodiments will be described.

In one example, a semiconductor device according to an embodiment serves as a photorelay device for transmitting AC signals and DC signals. Such a semiconductor device according to an embodiment is, for example, a package of electronic components. In the following description, AC signals and DC signals may be simply called “signals”.

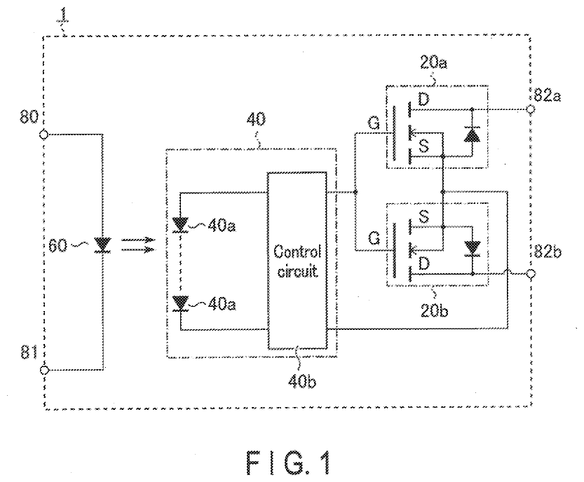

FIG. 1 will be referred to for describing an exemplary configuration of a semiconductor device according to one embodiment. FIG. 1 is a circuit diagram for illustrating an exemplary circuit configuration of a semiconductor device according to an embodiment.

This semiconductor device according to an embodiment, namely, a semiconductor device 1, includes terminals 80, 81, 82a, and 82b. The terminals 80 and 81 receive a voltage supply for driving the semiconductor device 1. The semiconductor device 1, while in the state of being driven, is capable of transmitting signals via the terminals 82a and 82b.

The exemplary circuit configuration of the semiconductor device according to an embodiment will be described in more detail using the same FIG. 1.

The semiconductor device 1 further includes metal-oxide-semiconductor field effect transistors (MOSFETs) 20a and 20b, a light receiver 40, and a light emitter 60.

The light emitter 60 is coupled to the terminals 80 and 81. The light emitter 60 is driven by the voltage supplied to the terminals 80 and 81.

In one example, the light receiver 40 includes multiple photodiodes 40a coupled in series, and a control circuit 40b. The light receiver 40 may include, for example, several to several tens of serially coupled photodiodes 40a. Both ends of the set of serially coupled photodiodes 40a are coupled to the control circuit 40b. The control circuit 40b utilizes photovoltaic power generated by these multiple photodiodes 40a to place the MOSFETs 20a and 20b in an ON state.

The MOSFETs 20a and 20b have their respective gates coupled in common to an anode electrode of the light receiver 40. The MOSFETs 20a and 20b have their respective sources coupled in common to a cathode electrode of the light receiver 40. The drain of the MOSFET 20a is coupled to the terminal 82a. The drain of the MOSFET 20b is coupled to the terminal 82b.

In the circuit configuration of the semiconductor device 1 as described above, light is emitted from the light emitter 60 toward the light receiver 40 in response to the light emitter 60 turning to the ON state (a lighting state) from the OFF state (a lights-out state). The light receiver 40 changes the MOSFETs 20a and 20b from the OFF state to the ON state using the voltage generated by an effect of the photovoltaic power. This establishes an electrical coupling between the terminals 82a and 82b. In this manner, the semiconductor device 1 transmits a signal fed to one of the terminals 82a and 82b to the other one of the terminals 82a and 82b via the MOSFETs 20a and 20b.

In response to the light emitter 60 turning to the OFF state from the ON state, the light emission from the light emitter 60 toward the light receiver 40 is stopped. This changes the MOSFETs 20a and 20b from the ON state to the OFF state. The semiconductor device 1 in this manner electrically insulates the terminals 82a and 82b from each other.

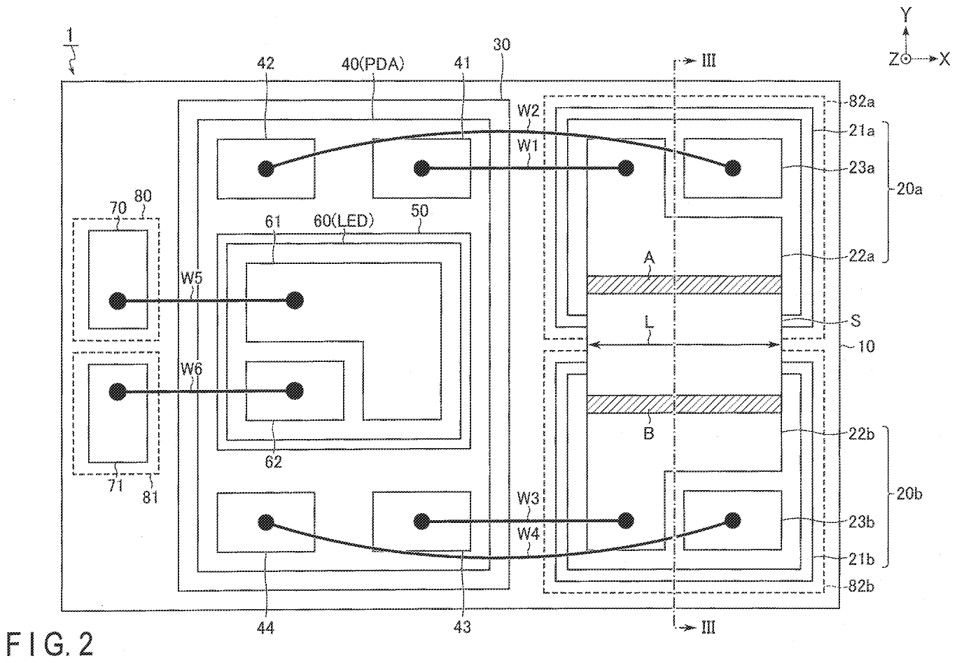

Next, FIG. 2 will be referred to for describing a planar structure of the semiconductor device 1 according to the embodiment. FIG. 2 is a plan view showing an exemplary planar structure of the semiconductor device according to the embodiment. Note that the description will assume a Z direction to be a direction perpendicular to the surface of a substrate constituting a part of the semiconductor device. It will be assumed that an X direction is a direction parallel to this surface of the substrate. It will also be assumed that a Y direction is a direction parallel to the surface of the substrate and orthogonal to the X direction.

The semiconductor device 1 further includes a substrate 10, a support 30, an adhesive layer 50, electrodes 70 and 71, and interconnects W1, W2, W3, W4, W5, W6, and S. For the sake of description, referring to a relationship between the arrangements of the substrate 10 and the MOSFET 20a in the Z direction, an end region where the MOSFET 20a is provided will also be called an “upper end region”, an “upper Z-direction end”, or the like. Referring to this Z-direction arrangement relationship, an end region where the substrate 10 is provided will also be called a “lower end region”, a “lower Z-direction end”, or the like.

In one example, the substrate 10 is constituted by polyimide-based flexible printed circuits (FPCs).

The MOSFETs 20a and 20b may each be, for example, an enhancement-type N-channel MOSFET. The MOSFETs 20a and 20b are arranged in the Y direction on or above the substrate 10. For the sake of description, referring to a relationship between the arrangements of the MOSFETs 20a and 20b in the Y direction, an end region where the MOSFET 20a is provided will also be called “one end region”, “one Y-direction end”, or the like. Referring to this Y-direction arrangement relationship, an end region where the MOSFET 20b is provided will also be called “the other end region”, “the other Y-direction end”, or the like.

In one example, the MOSFET 20a includes electrodes 21a, 22a, and 23a. The electrode 21a is located at the lower surface part of the MOSFET 20a and in contact with the substrate 10. The electrodes 22a and 23a are located at the upper surface part of the MOSFET 20a. The electrode 21a functions as a drain electrode of the MOSFET 20a. The electrode 22a functions as a source electrode of the MOSFET 20a. The electrode 23a functions as a gate electrode of the MOSFET 20a. In one example, the electrode 22a includes a first portion and a second portion in contact with each other and each having a rectangular shape. The second portion is located on the side of the other end region in the Y direction, as compared to the first portion and the electrode 23a. The second portion has an X-direction length larger than the X-direction length of the first portion.

In one example, the MOSFET 20b includes electrodes 21b, 22b, and 23b. The electrode 21b is located at the lower surface part of the MOSFET 20b and in contact with the substrate 10. The electrodes 22b and 23b are located at the upper surface part of the MOSFET 20b. The electrode 21b functions as a drain electrode of the MOSFET 20b. The electrode 22b functions as a source electrode of the MOSFET The electrode 23b functions as a gate electrode of the MOSFET 20b. In one example, the electrode 22b includes a first portion and a second portion in contact with each other and each having a rectangular shape. The second portion is located on the side of the one end region in the Y direction, as compared to the first portion and the electrode 23b. The second portion has an X-direction length larger than the X-direction length of the first portion.

In the structure as described above, the MOSFETs 20a and 20b are, for example, arranged symmetrically with respect to an X-Z plane. Here, for example, the electrodes 21a, 22a, and 23a are symmetrical to the electrodes 21b, 22b, and 23b, respectively, with respect to the X-Z plane. As such, the electrode 23a, the second portion of the electrode 22a, the second portion of the electrode 22b, and the electrode 23b are arranged in this order in the Y direction.

The support 30 supports the light receiver 40 and the light emitter 60. The support 30 may be either a conductive member or an insulative member. The support 30 has a shape of a plate extending in the X direction and the Y direction. In one example, the support 30 is provided on or above the substrate 10 so that it is arranged next to the MOSFETs 20a and 20b in the X direction.

The light receiver 40 may be, for example, a photodiode array (PDA), a phototransistor, or the like. The description will assume the light receiver 40 to be a PDA. The light receiver 40 is in contact with the upper surface of the support 30. In one example, the light receiver 40 is provided so that its upper surface serves as a light receiving surface.

The light receiver 40 includes electrodes 41 to 44. The electrodes 41 to 44 are located at the upper surface part of the light receiver 40. While the figure does not illustrate this, the electrodes 41 and 43 are electrically coupled to each other via, for example, the inside part of the light receiver 40. Also, while the figure does not illustrate this, the electrodes 42 and 44 are electrically coupled to each other via, for example, the inside part of the light receiver 40. In one example, the electrodes 41 and 43 function as an anode electrode of the light receiver 40. In one example, the electrodes 42 and 44 function as a cathode electrode of the light receiver 40.

The light emitter 60 may be, for example, a light emitting diode (LED) or the like. In one example, the light emitter 60 is arranged at a higher level than the light receiver 40. The light emitter 60 here includes a light emitting surface as its lower surface. That is, the light emitter 60 is provided so that it can emit light toward the light receiving surface of the light receiver 40.

The light emitter 60 includes electrodes 61 and 62. The electrodes 61 and 62 are located at the upper surface part of the light emitter 60. In one example, the electrode 61 functions as an anode electrode of the light emitter 60. In one example, the electrode 62 functions as a cathode electrode of the light emitter 60.

The adhesive layer 50 is provided between the light emitter 60 and the light receiver 40 and in contact with both the light emitter 60 and the light receiver 40. In one example, the adhesive layer 50 is an insulative material having a property of permitting light emitted from the light emitter 60 to pass through.

The electrodes 70 and 71 are located on or above the upper surface of the substrate 10.

In one example, the terminals 80, 81, 82a, and 82b are located in contact with the lower surface of the substrate 10.

The terminals 80 and 81 receive a voltage supply for driving the light emitter 60 from, for example, a non-illustrated power source. The terminal 80 is electrically coupled to the electrode 70 via a non-illustrated conductor penetrating through the substrate 10. The terminal 81 is electrically coupled to the electrode 71 via a non-illustrated conductor penetrating through the substrate 10.

The terminals 82a and 82b are each coupled to a circuit, etc., provided outside the semiconductor device 1. The terminal 82a is electrically coupled to the electrode 21a of the MOSFET 20a via a conductor penetrating through the substrate 10. The terminal 82b is electrically coupled to the electrode 21b of the MOSFET 20b via a conductor penetrating through the substrate 10.

The interconnects W1 to W6 are, for example, wires each formed by the wire bonding technique. The interconnects W1 to W6 are each constituted by a conductive material. The conductive material preferably has a low electrical resistivity. In one example, such a conductive material contains at least one element selected from aluminum, copper, silver, and gold. The interconnects W1 to W6 may also be endowed with a property of suppressing generation of copper ions so that luminance degradation of the light emitter 60 will be prevented. Note that each of the interconnects W1 to W6 may instead be a flexible substrate.

The interconnect W1 electrically couples the electrodes 22a and 41 to each other. More specifically, and for example, the interconnect W1 is in contact with the first portion of the electrode 22a, and the electrode 41. The interconnect W2 electrically couples the electrodes 23a and 42 to each other. The interconnect W3 electrically couples the electrodes 22b and 43 to each other. More specifically, and for example, the interconnect W3 is in contact with the first portion of the electrode 22b, and the electrode 43. The interconnect W4 electrically couples the electrodes 23b and 44 to each other. The interconnect W5 electrically couples the electrodes 61 and 70 to each other. The interconnect W6 electrically couples the electrodes 62 and 71 to each other.

In one example, the interconnect S is a conductor having a shape of a sheet, different from a wire. The sheet-shaped conductor here refers to, for example, a conductive member capable of contacting an electrode via an area having a wider width than the width of an area of contact between a wire and the electrode. The width of an area of contact between each interconnect and an electrode refers to, for example, the size of the area in a direction orthogonal to the direction in which the interconnect extends to couple two electrodes to each other as viewed from the top, that is, in the X-Y plane. As one concrete example, the interconnect S according to the embodiment is a conductive ribbon formed by the ribbon bonding technique. A conductive material constituting the interconnect S preferably has a low electrical resistivity. In one example, this conductive material contains at least one element selected from aluminum, copper, silver, and gold. The interconnect S may also include, for example, a conductive layer containing nickel, gold, etc. and formed through plating on the conductive material. The interconnects S may be endowed with a property of suppressing generation of copper ions so that luminance degradation of the light emitter 60 will be prevented.

In one example, one Y-direction end of the interconnect S is in contact with the second portion of the electrode 22a. The other Y-direction end of the interconnect S is in contact with the second portion of the electrode 22b. With this structure of the interconnect S, an electrical coupling between the source of the MOSFET 20a and the source of the MOSFET 20b is established.

In one example, the interconnect S is formed to have an X-direction length L equivalent or comparable in size to each of the X-direction length of the second portion of the electrode 22a and the X-direction length of the second portion of the electrode 22b. Accordingly, an area A of contact between the interconnect S and the electrode 22a and an area B of contact between the interconnect S and the electrode 22b in this example each have the X-direction length L. Assuming an example where each of the interconnects W1 to W6 is a wire, the length L is larger than the width of an area of contact between each of the interconnects (wires) W1 to W6 and one of the electrodes coupled by the interconnect (wire). That is, in instances where each of the interconnects W1 to W6 is a wire, the interconnect S contacts the electrodes 22a and 22b via respective areas each having a width larger than the width of an area of contact between each of the interconnects (wires) W1 to W6 and one of the electrodes coupled by the interconnect (wire).

Note that, while FIG. 2 shows an example where the interconnect S has an X-direction length L equivalent or comparable in size to each of the X-direction length of the second portion of the electrode 22a and the X-direction length of the second portion of the electrode 22b, no limitation is intended by this example. The X-direction length L of the interconnect S may be smaller or longer than each of the X-direction length of the second portion of the electrode 22a and the X-direction length of the second portion of the electrode 22b.

Also, while FIG. 2 assumes an example where the semiconductor device 1 includes one interconnect S for coupling the electrodes 22a and 22b together, no limitation is intended. The semiconductor device 1 may include two or more interconnects for coupling the electrodes 22a and 22b together.

In one example, the semiconductor device 1 is protected by a non-illustrated sealing member. Such a sealing member is provided to cover the MOSFETs 20a and 20b, the support 30, the light receiver 40, the light emitter 60, the terminals 80, 81, 82a, and 82b, the electrodes 70 and 71, and the interconnects W1 to W6 and S.

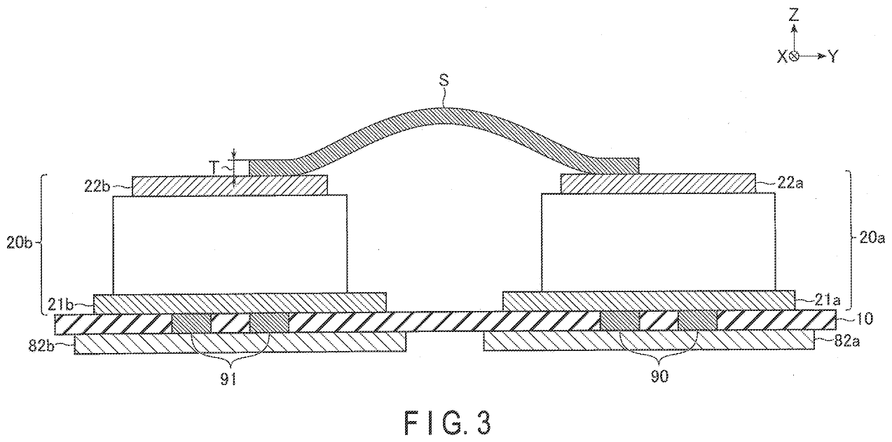

FIG. 3 will be referred to for describing an exemplary sectional structure of the semiconductor device 1 according to one embodiment. FIG. 3 is a sectional view taken along the line III-III indicated in FIG. 2, and shows an exemplary sectional structure of the semiconductor device 1 according to the embodiment.

In the cross-section shown in FIG. 3, the semiconductor device 1 includes two conductors 90 and two conductors 91, in addition to the substrate 10, the MOSFETs and 20b, the terminals 82a and 82b, and the interconnect S.

Each of the conductors 90, as well as each of the conductors 91, penetrates through the substrate 10. Each of the conductors 90 electrically couples the electrode 21a with the terminal 82a. Each of the conductors 91 electrically couples the electrode 21b with the terminal 82b. Note that the embodiment is described using an example where the semiconductor device 1 includes two conductors 90 and two conductors 91, but no limitation is intended by this. The number of conductors 90 in the semiconductor device 1 may be one, or three or more. Also, the number of conductors 91 in the semiconductor device 1 may be one, or three or more.

The interconnect S includes an arch portion between its one Y-direction end and its other Y-direction end. For example, this arch portion is formed by the ribbon bonding technique.

The interconnect S has a thickness T in the Z direction. In one example, this thickness T is smaller than the X-direction length L of the interconnect S, i.e., T<L.

According to one or more embodiments, transmission characteristics for high-frequency signals can be improved. High-frequency signals here are, for example, signals having a frequency of 20 GHz or greater.

According to an embodiment, a semiconductor device 1 includes MOSFETs 20a and 20b each provided on a substrate 10, a light emitter 60, a light receiver 40 which places the MOSFETs 20a and 20b in an ON state or an OFF state according to the state of the light emitter 60, and an interconnect S electrically coupling an electrode 22a of the MOSFET 20a and an electrode 22b of the MOSFET 20b. The interconnect S according to one embodiment is a conductive ribbon formed by ribbon bonding. With such a structure, an increase in resistance between the source of the MOSFET 20a and the source of the MOSFET 20b can be suppressed. Accordingly, the semiconductor device 1 can prevent its transmission characteristics in the high frequency band from being degraded due to the increase in resistance between the source of the MOSFET 20a and the source of the MOSFET 20b.

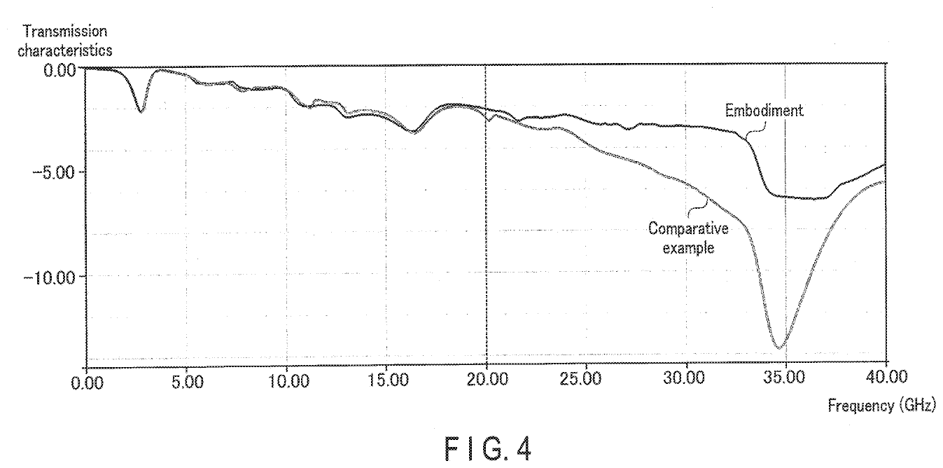

More specifically, the semiconductor device 1 according to the embodiment employs the interconnect S formed by ribbon bonding for coupling the electrodes 22a and 22b to each other. This can form an area A of contact between the interconnect S and the electrode 22a and an area B of contact between the interconnect S and the electrode 22b, each being wider than the area of contact between a wire and the source of each MOSFET, formed in the instance of coupling the sources of two MOSFETs to each other using the wire (also called a “comparative example” below). The embodiment can therefore suppress the resistance between the electrodes 22a and 22b in the high frequency band. Consequently, as shown in FIG. 4, the degradation of the transmission characteristics of the semiconductor device 1 in the high frequency band can be prevented. FIG. 4 is a graph showing changes in transmission characteristics with respect to frequencies in each of the case of using the semiconductor device 1 according to the embodiment and the case of using a semiconductor device according to the comparative example. FIG. 4 shows the simulation results from the respective cases of the embodiment and the comparative example. In FIG. 4, the vertical axis corresponds to values of transmission characteristics, and the horizontal axis corresponds to frequencies (GHz). The comparative example shown in FIG. 4 adopts a structure in which the sources of two MOSFETs are coupled to each other by two wires. As shown in FIG. 4, the transmission characteristics exhibited by the semiconductor device 1 according to the embodiment are superior to the transmission characteristics of the semiconductor device according to the comparative example in the respects of, for example, maintaining high values in the high frequency band of 20 GHz or higher.

According to one embodiment, the interconnect S, the second portion of the electrode 22a, the second portion of the electrode 22b, the area A, and the area B each have a comparable X-direction length L. With such a structure, an impedance mismatch is prevented from occurring at the boundary between the electrode 22a and the interconnect S, and at the boundary between the electrode 22b and the interconnect S. Accordingly, signal reflection due to an impedance mismatch is suppressed during the transmission of signals from the electrode 22a or 22b to the interconnect S. Consequently, the embodiment can suppress the turbulence in signal transmission characteristics, and also the degradation of the signal transmission characteristics, which could otherwise occur due to an impedance mismatch.

According to one embodiment, the semiconductor device 1 can realize a reduced number of interconnects between the electrodes 22a and 22b as compared to the case of coupling the sources of two MOSFETs to each other using multiple wires. More specifically, the embodiment uses a ribbon to couple the electrode 22a of the MOSFET 20a and the electrode 22b of the MOSFET 20b to each other. This can avoid the increase in the number of interconnects while securing suitable sizes of the cross-section of the interconnect and the area of contact between the interconnect and the source. Accordingly, a magnetization interference between different interconnects does not occur. Consequently, the embodiment can prevent the degradation of transmission characteristics due to a magnetization interference. Moreover, keeping the number of interconnects from increasing can also prevent an increase in production costs.

Coupling the electrodes 22a and 22b to each other using multiple wires requires a wire bonding process to be performed multiple times. This could result in an unintended inclination of the semiconductor device structure. According to one embodiment, which does not increase the number of interconnects between the electrode 22a and 22b, only a small number of bonding processes is required. This can suppress the occurrence of an inclination of the structure or structural components of the semiconductor device 1. Consequently, the production of semiconductor devices 1 with a poor quality can be prevented, and increase in the yield of semiconductor devices 1 can be realized.

According to one embodiment, the second portion of the electrode 22a and the second portion of the electrode 22b are arranged between the electrodes 23a and 23b in the Y direction. With such a layout, the interconnect S can have a larger X-direction length as compared to, for example, a layout in which each area of contact between one of the source electrodes of two respective MOSFETs and the interconnect is arranged in the X direction in line with the gate electrodes.

### 2. Modifications

Semiconductor devices according to exemplary modifications will be described. The description will in principle omit configurations or structures, etc., which are the same or substantially the same as those of the foregoing embodiments, and concentrate on configurations or structures, etc., different from those of the foregoing embodiments.

### 2.1. First Modification

The foregoing embodiments have assumed that the interconnect S is a conductor formed by ribbon bonding, but the interconnect S is not limited to such a form. The interconnect S may be a metal plate or a shaped metal member.

A description will be mainly given of the particulars of the configurations and the structures of the semiconductor device 1 according to the first modification, as constituting differences from the semiconductor device according to the foregoing embodiments.

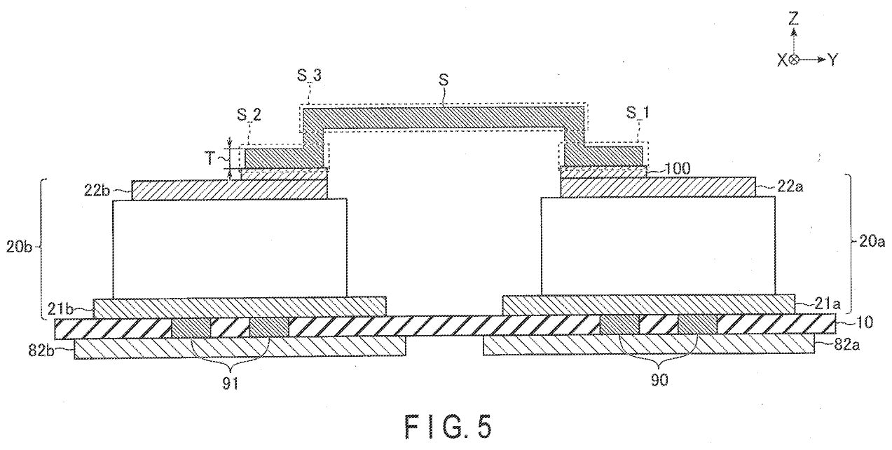

The circuit configuration and the planar structure of the semiconductor device 1 according to the first modification are substantially equivalent to those of the semiconductor device according to the foregoing embodiments as shown in FIGS. 1 and 2. Below, FIG. 5 will be referred to for describing a sectional structure of the semiconductor device 1 according to the first modification. FIG. 5 is a sectional view showing an exemplary sectional structure of the semiconductor device 1 according to the first modification. This sectional structure shown in FIG. 5 corresponds to the structure of the foregoing embodiments shown in FIG. 3.

In the cross-section shown in FIG. 5, the semiconductor device 1 according to the first modification includes conductors 100, in addition to the substrate 10, the MOSFETs 20a and 20b, the terminals 82a and 82b, the conductors 90 and 91, and the interconnect S. The substrate 10, the MOSFETs 20a and 20b, the terminals 82a and 82b, and the conductors 90 and 91 of the semiconductor device 1 according to the first modification have equivalent or comparable configurations and structures to those of the substrate 10, the MOSFETs 20a and 20b, the terminals 82a and 82b, and the conductors 90 and 91 of the semiconductor device 1 according to the foregoing embodiments. Here, the configurations and structures of the interconnect S and the conductors 100 will be mainly discussed.

The interconnect S shown in FIG. 5 is, for example, a shaped metal member. One Y-direction end and the other Y-direction end of the interconnect S are coupled to the electrodes 22a and 22b via the conductors 100, respectively. Each conductor 100 is formed by, for example, soldering so that it can electrically couple the interconnect S with the electrode 22a, or the interconnect S with the electrode 22b. The conductors 100 may instead or additionally be formed using a conductive paste.

The interconnect S here includes a portion S_1, a portion S_2, and a portion S_3. The portion S_1 contacts one conductor 100 at the one Y-direction end and has a rectangular cross-section. The portion S_2 contacts another conductor 100 at the other Y-direction end and has a rectangular cross-section. The portion S_3 electrically couples the portion S_1 and the portion S_2 to each other and has a rectangular cross-section. The lower surface of the portion S3 is positioned at a higher level than, for example, the lower surfaces of the portion S_1 and the portion S_2.

Note that, while not illustrated in the figure, the interconnect S in this first modification is capable of contacting each conductor 100 via an area having a wider width than the width of an area of contact between a wire and the electrode. The width of the area of contact between the interconnect S and each conductor 100 refers to, for example, the size of the area in the X direction.

Also note that, while FIG. 5 shows an example where the interconnect S is a metal member constituted by the portion S_1, the portion S_2, and the portion S_3 having a lower surface positioned at a higher level than the lower surfaces of the portions S_1 and S_2, the interconnect S in the modification is not limited to this. As mentioned above, the interconnect S may be a metal member having a flat shape.

According to the first modification, as in the foregoing embodiments, transmission characteristics for high-frequency signals can be improved. The first modification can also suppress the turbulence in signal transmission characteristics and the degradation of the signal transmission characteristics which could otherwise occur due to an impedance mismatch. Moreover, the first modification does not increase the number of interconnects, and therefore, the first modification can prevent the degradation of transmission characteristics due to a magnetization interference. The first modification as such can also prevent an increase in production costs. Moreover, the production of semiconductor devices 1 with a poor quality can be prevented, and an increase in the yield of semiconductor devices 1 can be realized. Further, the interconnect S in this modification can also have a larger X-direction length as compared to, for example, a layout in which each area of contact between one of the source electrodes of two respective MOSFETs and the interconnect is arranged in the X direction in line with the gate electrodes.

### 2.2. Second Modification

The foregoing embodiments and the first modification have assumed that the interconnect S is a ribbon conductor, a shaped metal member, or a metal plate. The interconnect S may instead be a flexible substrate.

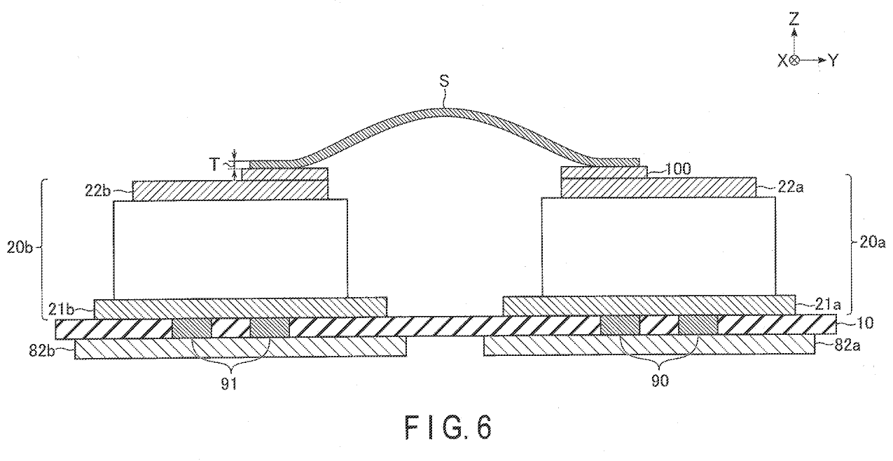

The circuit configuration and the planar structure of the semiconductor device 1 according to the second modification are substantially equivalent to those of the semiconductor devices according to the foregoing embodiments and the first modification. FIG. 6 will be referred to for describing a sectional structure of the semiconductor device 1 according to the second modification. FIG. 6 is a sectional view showing an exemplary sectional structure of the semiconductor device 1 according to the second modification. This sectional structure shown in FIG. 6 corresponds to the structure of the foregoing embodiments shown in FIG. 3.

In the cross-section shown in FIG. 6, the semiconductor device 1 according to the second modification includes the substrate 10, the MOSFETs 20a and 20b, the terminals 82a and 82b, the conductors 90, 91, and 100, and the interconnect S. The substrate 10, the MOSFETs 20a and 20b the terminals 82a and 82b, and the conductors 90, 91, and 100 of the semiconductor device 1 according to the second modification have equivalent or comparable configurations and structures to those of the substrate 10, the MOSFETs 20a and 20b, the terminals 82a and 82b, and the conductors 90, 91, and 100 of the semiconductor device 1 according to the first modification. Here, the configuration and structure of the interconnect S will be mainly discussed.

The interconnect S according to the second modification is a flexible substrate.

As in the configuration of the interconnect S according to the first modification, the interconnect S according to the second modification is electrically coupled to the electrode 22a via one conductor 100 at the one Y-direction end (a first end). Also, the interconnect S according to the second modification is electrically coupled to the electrode 22b via another conductor 100 at the other Y-direction end (a second end).

The structure of the interconnect S according to the second modification is substantially the same as that of the interconnect S according to the foregoing embodiments, except that the interconnect S of the former is electrically coupled to the electrodes 22a and 22b via the respective conductors 100 as described above. That is, the interconnect S according to the second modification includes an arch portion.

According to the second modification, as in the foregoing embodiments and the first modification, transmission characteristics for high-frequency signals can be improved. The second modification can also suppress the turbulence in signal transmission characteristics and the degradation of the signal transmission characteristics which could otherwise occur due to an impedance mismatch. Moreover, the second modification does not increase the number of interconnects, and therefore, the second modification can prevent the degradation of transmission characteristics due to a magnetization interference. The second modification as such can also prevent an increase in production costs. Moreover, the production of semiconductor devices 1 with a poor quality can be prevented, and an increase in the yield of semiconductor devices 1 can be realized. Further, the interconnect S in the second modification can also have a larger X-direction length as compared to, for example, a layout in which each area of contact between one of the source electrodes of two respective MOSFETs and the interconnect is arranged in the X direction in line with the gate electrodes.

Still more, with the interconnect S constituted by a flexible substrate, the second modification can prevent the semiconductor device 1 from being damaged in the event of occurrence of a stress within the semiconductor device 1.

### 3. Others

While certain embodiments have been described, they have been presented by way of example only, and are not intended to limit the scope of the inventions. Indeed, the novel embodiments described herein may be embodied in a variety of other forms. Furthermore, various omissions, substitutions, and changes in the form of the embodiments may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a first element and a second element on or above a first surface of the substrate, the first element and the second element each including a first terminal, a second terminal, and a gate;
a light emitter;
a light receiver configured to place the first element and the second element in an ON state or an OFF state according to an emitting state of the light emitter; and
a first interconnect electrically coupling the first terminal of the first element and the first terminal of the second element to each other,
the first interconnect being a sheet-shaped conductor.

2. The device of claim 1, wherein
the first element and the second element are arranged in a first direction defining a plane of the first surface,
the first terminal and the gate of the first element are located at an upper surface of the first element,
the first terminal and the gate of the second element are located at an upper surface of the second element,
the first terminal of the first element includes a first sub-portion located between the gate of the first element and the gate of the second element in the first direction,
the first terminal of the second element includes a second sub-portion located between the gate of the first element and the gate of the second element in the first direction, and
the first interconnect is in contact with each of the first sub-portion and the second sub-portion.

3. The device of claim 2, wherein
the first terminal of the first element includes a third sub-portion arranged in a second direction with the gate of the first element, the second direction being orthogonal to the first direction and defining the plane of the first surface,
the first terminal of the second element includes a fourth sub-portion arranged in the second direction with the gate of the second element,
the third sub-portion is in contact with a second interconnect,
the fourth sub-portion is in contact with a third interconnect, and
the second interconnect and the third interconnect are electrically coupled to the light receiver.

4. The device of claim 1, further comprising
a second interconnect electrically coupling the light receiver and the first terminal of the first element to each other,
a third interconnect electrically coupling the light receiver and the gate of the first element to each other,
a fourth interconnect electrically coupling the light receiver and the first terminal of the second element to each other, and
a fifth interconnect electrically coupling the light receiver and the gate of the second element to each other,
wherein the second interconnect, the third interconnect, the fourth interconnect, and the fifth interconnect each comprise a wire.

5. The device of claim 1, wherein the first interconnect comprises a conductive ribbon formed by ribbon bonding.

6. The device of claim 1, wherein the first interconnect comprises a metal plate or a shaped metal member.

7. The device of claim 1, wherein the first interconnect comprises a flexible substrate.

8. The device of claim 1, wherein
the first element and the second element are arranged in a first direction defining a plane of the first surface, and
the first interconnect contacts, in a second direction, an entirety of the first terminal of the first element and an entirety of the first terminal of the second element, the second direction being orthogonal to the first direction and defining the plane of the first surface.

9. The device of claim 8, wherein a width of the first terminal of the first element in the second direction, a width of the first terminal of the second element in the second direction, and a width of the first interconnect in the second direction are substantially equal to one another.

10. The device of claim 1, further comprising a second interconnect electrically coupling the first terminal of the first element and the first terminal of the second element to each other, the second interconnect being a sheet-shaped conductor.

11. The device of claim 1, wherein a width of the first interconnect is larger than a thickness of the first interconnect in a first direction being orthogonal to the plane of the first surface,
the width of the first interconnect being orthogonal to the first interconnect extending direction.

12. The device of claim 4, wherein a width of the first interconnect is larger than each of a width of the second interconnect, a width of the third interconnect, a width of the fourth interconnect, and a width of the fifth interconnect,
the width of the first interconnect, the second interconnect, the width of the third interconnect, the width of the fourth interconnect, and the width of the fifth interconnect being orthogonal to respective interconnect extending directions.

13. The device of claim 2, wherein a set of the first element and the second element, and the light receiver are arranged in a second direction orthogonal to the first direction and defining the plane of the first surface.

14. The device of claim 1, further comprising an adhesive layer, wherein
the light emitter comprises a portion located at a higher level than the light receiver such that an emitting surface of the light emitter faces a light receiving surface of the light receiver, and
the adhesive layer is located between the light emitter and the light receiver and in contact with the emitting surface of the light emitter and the light receiving surface of the light receiver.
